(19) United States
(12) Patent Application Publication
(10) Pub. No.: US 2016/0254128 A1
(43) Pub. Date: Sep. 1, 2016

(54) SPUTTERING TARGET AND PROCESS FOR PRODUCING IT

(71) Applicant: PLANSEE SE, Reutte (AT)

(72) Inventors: NIKOLAUS REINFRIED, LECHASCHAU (AT); MICHAEL SCHOBER, BREITENWANG (AT); WOLFRAM KNABL, REUTTE (AT); JOERG WINKLER, REUTTE (AT)

(21) Appl. No.: 15/033,427

(22) PCT Filed: Oct. 27, 2014
(86) PCT No.: PCT/AT2014/000195

§ 371 Date: Apr. 29, 2016

(30) Foreign Application Priority Data
Oct. 29, 2013 (AT) GM 354/2013

(51) Int. Cl. H01J 37/34; C23C 14/14; C23C 14/34; B22F 3/20; B22F 3/16; B22F 3/17; B22F 3/18; C22C 27/04; B22F 1/00

(52) U.S. Cl. CPC H01J 37/3429; C22C 27/04; C23C 14/14; C23C 14/3414; H01J 37/3491; B22F 1/0003; B22F 3/16; B22F 3/17; B22F 3/18; B22F 3/20; H01J 37/3423; H01J 37/342; B22F 2201/10; B22F 2201/20; B22F 2201/01; B22F 2301/20

(57) ABSTRACT

A sputtering target is composed of an Mo alloy containing at least one metal of group 5 of the Periodic Table, where the average content of group 5 metal is from 5 to 15 at % and the Mo content is ≧80 at %. The sputtering target has an average C/O ratio in (at %/at %) of ≧1. The sputtering targets can be produced by shaping or forming and have an improved sputtering behavior.

The invention relates to a sputtering target which comprises molybdenum (Mo) and at least one metal of group 5 of the Periodic Table, where the average content C_{M} of group 5 metal is from 5 to 15 at % and the Mo content is ≧80 at %.

Sputtering, also referred to as cathode atomization, is a physical process in which atoms are detached from a sputtering target by bombardment with high-energy ions and go over into the gas phase. Sputtering targets which are composed of Mo and contain group 5 metals are known.

Thus, EP 0 285 130 A1 describes a sputtering target composed of an Mo alloy containing from 50 to 85 at % of tantalum (Ta). JP 2002 327264 A discloses a sputtering target composed of an Mo alloy which contains from 2 to 50 at % of niobium (Nb) and/or vanadium (V) and has a relative density of >95%, a flexural strength of >300 MPa and a particle size of <300 μm. The sputtering target has a diffusion phase and at least one pure phase or only a diffusion phase. JP 2005 307226 A discloses a sputtering target composed of an Mo alloy containing from 0.1 to 50 at % of a transition metal. The sputtering target has a length of ≧1 m and a homogeneous density of ≧98%. As an alternative, JP 2005 307226 A discloses a sputtering target which has fluctuations in the composition of ≦20% over the total length.

Mo—Nb and Mo—Ta sputtering targets are used, for example, for producing electrode layers for thin film transistors or producing contact layers for touch panels. To meet the increasing demands in terms of layer quality and homogeneity, and this at ever increasing dimensions, is the objective of numerous development activities.

Thus, JP 2008 280570 A describes a production process for an Mo—Nb sputtering target having an Nb content of from 0.5 to 50 at %, in which an Mo sintered body is firstly produced and is then crushed to give powder. The Mo powder produced in this way is subjected to a reducing treatment and mixed with Nb powder. This mixture is subsequently densified by hot isostatic pressing.

Although this process makes it possible to reduce the oxygen content of the powder, it does not allow a further reduction of the oxygen content in the sputtering target to be achieved since hot isostatic pressing is carried out in a closed container (can). In addition, it is also not possible to disperse Nb in the Mo in a homogeneity required for many applications.

JP 2005 290409 A in turn describes a sputtering target composed of an Mo alloy containing from 0.5 to 50 at % of a metal from the group consisting of Ti, Zr, V, Nb and Cr, where the oxygen comprised in the target is present in the form of oxides in the interface region of Mo-rich phase/alloying element-rich phase. The preferred production method for this comprises the steps of mixing of Mo powder and powder of the alloying element, sintering, crushing of the sintered body to give powder and densification of the powder produced in this way by hot isostatic pressing in the canned state. The oxides have an adverse effect on the homogenization of the sputtering target during hot pressing since the grain boundary diffusion rate is reduced. In addition, the oxides have an adverse effect on the sputtering behaviour.

JP 2013 83000 A describes the production of a sputtering target composed of an Mo alloy containing from 0.5 to 60 at % of one or more elements from the group consisting of Ti, Nb and Ta, in which Mo powder is mixed with a hydride powder of the alloying element, and this mixture is degassed at from 300° C. to 1000° C. and subsequently densified by hot isostatic pressing. Although the hydride powder decomposes during degassing to form the metal powder, oxygen is taken up again by adsorption on surfaces of the powder particles during further processing steps. This oxygen is not removed during hot isostatic pressing.

The sputtering targets described do not meet the increasing requirements in respect of layer homogeneity, homogeneity of the sputtering behaviour and avoidance of undesirable local partial melting. Local partial melting is caused, for example, by arc processes (local formation of an electric arc).

The production technologies described do not make it possible to produce sputtering targets which meet the above-described requirements, for at least one of the following reasons:
a) oxides hinder grain boundary diffusion;
b) oxygen removal during the consolidation process is not possible;
c) the consolidation process does not lead to sufficient homogenization of the alloying elements;
d) interface and grain boundary volumes and also defect density which are partly responsible for a sufficiently high diffusion rate are not high enough;
e) the consolidation process leads to an unacceptably high coarsening of the grains;
f) the powder used leads to a coarse-grain sputtering target.

It is an object of the present invention to provide a sputtering target which meets the above-described requirements and/or does not have the above-described deficiencies. In particular, it is an object of the invention to provide a sputtering target by means of which a very homogeneous layer, both in respect of the chemical composition and also in respect of layer thickness distribution, can be produced and which does not have a tendency for local partial melting to occur as a result of arc processes. In addition, the sputtering target should have uniform sputtering behaviour. For the present purposes, uniform sputtering behaviour means that the individual grains or the individual regions of the sputtering target can be removed at the same rate, so that no relief structure is formed in the region of the sputtered surface during the sputtering process.

A further object of the present invention is to provide a production route which allows, in a simple and constant-process manner, the manufacture of a sputtering target which has the abovementioned properties.

The object is achieved by the independent claims. Particular embodiments are described in the dependent claims.

The sputtering target comprises Mo and at least one metal of group 5 of the Periodic Table. Group 5 metals are Ta, Nb and V. The average content C_{M} of group 5 metal is from 5 to 15 at %, while the Mo content is ≧80 at %. The group 5 metal is preferably completely dissolved in the Mo, which has a favourable effect on a uniform sputtering behaviour. For the present purposes, completely dissolved means that the content of group 5 metal present in elemental form (as Ta, Nb and/or V grains) or as oxide is <1% by volume. The sputtering target has an average C/O (carbon/oxygen) ratio in (at %/at %) of ≧1, preferably ≧1.2. To determine the average C/O ratio, three central samples and three edge samples are taken from the sputtering target and analysed and the average is calculated. The carbon is determined by combustion analysis (CA), and the oxygen is determined by carrier gas hot extraction (HE). In the following text, the average C/O ratio is referred to as C/O ratio.

Group 5 metals in the dissolved state have a strong mixed crystal-hardening effect on Mo. The mixed crystal hardening is associated with a significant reduction in the ductility and the forming capability. While two-phase (Mo-rich phase+group 5 metal-rich phase) alloys can be processed in a simpler and more constant-process manner by forming since the group 5 metal-rich phase has a ductilizing effect, this has to date not been possible in the case of very homogeneous mixed crystal alloys. A C/O ratio of ≧1 now ensures that the production process can include a forming step, while process-reliable manufacture by forming is not ensured to a sufficient extent at a C/O ratio of <1. The reason is presumably that a C/O ratio of ≧1 leads to an increase in the grain boundary strength, as a result of which grain boundary cracks can be avoided. How the forming step has a positive effect on the properties of the sputtering target will be explained in detail below. A C/O ratio in (at %/at %) of ≧1 now makes it possible for the first time to combine the positive effects of alloy homogeneity and forming texture in one product. A C/O ratio of ≧1 surprisingly not only has a positive effect on formed sputtering targets but also has a favourable influence on the sputtering behaviour of sputtering targets which have only been sintered or have been sintered and densified by hot isostatic pressing. Hot isostatic pressing here is preferably carried out without use of a can. How a C/O ratio of ≧1 can be set in a constant-process manner will be described in detail below. The C/O ratio of ≧1 also makes it possible to set a low oxygen content in the sputtering target. An oxygen content of ≦0.04 at %, preferably ≦0.03 at %, particularly preferably ≦0.02 at %, can be achieved. The sputtering target is preferably free of oxides. Undesirable arc processes can thus be reliably avoided. For the purposes of the present invention, free of oxides means that in a magnification by means of a scanning electron microscope at a magnification of 1000×, the number of detectable, oxidic particles in a region of 0.01 mm² is ≦1. The number of detectable, oxidic particles in a region of 0.1 mm² is preferably ≦1.

Furthermore, the sputtering target preferably has a forming texture. A forming texture comes about, as the name suggests, in a forming process. A forming texture is not lost in a subsequent heat treatment, for example a recovery heat treatment or a recrystallization heat treatment. The sputtering target of the invention can therefore be in an as-formed, recovered, partially recrystallized or fully recrystallized state. The forming texture can, for example, be attributable to a rolling, forging or extrusion process. The forming process forms grains which to a large extent have the same or similar orientation relative to the surface of the sputtering target. This makes the sputtering behaviour uniform since the removal rate depends on the orientation of the grains.

It is also advantageous for a uniform sputtering removal for the forming texture to have the following dominant orientations:
a. in the forming direction: 110
b. perpendicular to the forming direction: at least one orientation from the group 100 and 111.

If the direction has been altered during forming, as is possible in the case of plate-like geometries, the forming direction is considered to be the direction in which forming was greater (with a higher degree of deformation). The dominant orientation is considered to be the orientation of greatest intensity. The intensity is typically greater than 1.5 times, preferably two times, the random intensity.

The forming texture is determined by means of SEM (scanning electron microscope) and EBSD (electron backscatter diffraction). The sample is for this purpose installed at an angle of 70°. The incident primary electron beam is inelastically scattered by the atoms of the sample. When some electrons impinge on the lattice planes in such a way that the Bragg condition is satisfied, constructive interference occurs. This amplification occurs for all lattice planes in the crystal, so that the resulting diffraction pattern (electron backscatter pattern, also known as Kikuchi pattern) includes all angle relationships in the crystal and thus also the crystal symmetry. The measurement is carried out under the following conditions:
acceleration voltage: 20 kV,
orifice 120 μm,
working distance 22 mm
high current mode—activated
area scanned: 1761×2643 μm².
index step: 3 μm.

The preferred density of the sputtering target, based on the theoretical density of the respective composition, is >88% in the only sintered state, >96% in the sintered and hot isostatically densified state and >99.5%, preferably >99.9%, in the formed state. The high density in combination with the low oxygen content also ensures arc-free sputtering.

Furthermore, it is advantageous for the d₅₀ and the d₉₀ of the grain size distribution, measured perpendicular to the last forming direction, to satisfy the following relationship: d₉₀/d₅₀≦5.

d₉₀/d₅₀ is preferably ≦3, particularly preferably ≦1.5.

To determine the grain size, a polished section is produced and the grain boundaries are made visible by means of EBSD. The evaluation of the average and maximum grain size is then carried out by quantitative metallography. The evaluation is carried out in accordance with ASTM E 2627-10. A grain boundary is defined by the orientation difference between two adjacent grains being ≧5°. The grain size distribution with d₉₀ and d₅₀ is determined by means of quantitative image analysis. It has been found that a narrow grain size distribution has a very positive influence on the homogeneity of the sputtering behaviour. In contrast to other materials, Mo-group 5 metal sputtering targets sputter off grains having a relatively large grain diameter to a greater extent than grains having a smaller grain diameter. The cause is still unclear, but could be attributable to a different defect density or a channeling effect (lattice guiding effect—penetration of an ion because of linear regions without lattice atoms). This unfavourable non uniform sputtering behaviour can be virtually prevented by the abovementioned d₉₀/d₅₀ ratio.

The group 5 metal is dissolved not only completely but also extraordinarily uniformly in the Mo. The standard deviation a of the group 5 metal distribution measured by SEM/WDX preferably satisfies the relationship σ≦C_{M}×0.15, particularly preferably σ≦C_{M}×0.1.

Since the sputtering rate depends on the respective alloying element content, a sputtering target having a very homogeneous group 5 metal distribution according to the invention has an extremely uniform sputtering behaviour. This uniform sputtering behaviour results, firstly, in the layers produced having an extremely homogeneous thickness distribution, and secondly in the sputtering target always having, even after prolonged use, a low surface roughness/relief formation. This is in turn a prerequisite for a uniform sputtering behaviour over a long period of time.

Furthermore, the group 5 metal is preferably Ta and/or Nb. Mo—Ta and Mo—Nb alloys have a particularly advantageous corrosion and etching behaviour. The alloy advantageously consists of Mo and from 5 to 15 at % of group 5 metal and typical impurities. Typical impurities are both impurities which are usually present in the raw materials or can be attributed to the production process.

A sputtering target according to the invention is particularly advantageously configured as a tubular target. It has been found that under the conventional sputtering conditions for tubular targets, microstructural features such as oxides, homogeneity or the ratio of the average grain size to the maximum grain size have a stronger influence than is the case for flat targets.

The sputtering target of the invention can be produced in a particularly simple and constant-process manner when the process comprises the following steps:
production of a powder mixture comprising:
i. ≧80 at % of Mo powder;
ii. powder of at least one group 5 metal, with the content of group 5 metal in the powder mixture being from 5 to 15 at %; and
iii. a C source, with the amount of C being selected so that the total content of CΣ_{C} in at % and the total content of O Σ_{O} in at % in the powder mixture satisfy the following relationship:

0.2≧Σ_{C}/Σ_{O}≦1.2; and
consolidation of the powder mixture.

A Σ_{C}/Σ_{O} ratio in the range from 0.2 to 1.2 ensures that a CIO ratio of ≧1 can be set in the sputtering target. The removal of oxygen during further process steps preferably occurs by reaction of the oxygen with carbon and hydrogen.

The total content Σ_{O} of oxygen in the powder mixture comprises the oxygen content of the Mo powder and the oxygen content of the group 5 metal. The oxygen is mainly present in adsorbed form on the surface of the powder particles. In the case of conventional production and storage, the oxygen content of the Mo powder at a Fisher particle size of from 2 to 7 μm is typically from 0.1 to 0.4 at %. In the case of group 5 metals having a particle size measured by the Fisher method of from 4 to 20 μm, the oxygen content is typically from 0.3 to 3 at %. The total content Σ_{C} of carbon comprises the carbon content of the Mo powder, the carbon content of the group 5 metal and the carbon content of the C source. The carbon source can be, for example, carbon black, activated carbon or graphite powder. However, it can also be a carbon-releasing compound, for example Nb carbide or Mo carbide.

The oxygen and carbon content of the powders used is firstly determined by conventional methods and the required amount of powder of the C source is then determined. The powders are then mixed and consolidated by conventional methods. For the purposes of the present invention, the term consolidation refers to processes which lead to densification. Consolidation is preferably effected by cold isostatic pressing and sintering. For the present purposes, the term sintering refers to processes in which the densification is attributable only to the action of heat and not to pressure (as in the case of, for example, hot isostatic pressing).

During a heat treatment, preferably during the sintering process, the carbon of the carbon source reacts with the oxygen present in the powder to form CO₂ and in a lesser proportion CO. This reaction preferably occurs at temperatures at which the sintered body still has open porosity. Densification processes in which the material to be densified is present in a can, as is the case in, for example, hot isostatic pressing, are less suitable for using the process of the invention in an advantageous way. If hot isostatic pressing is carried out using a can, the inventive powder mixture has to be subjected to a separate heat treatment/degassing treatment.

The total carbon content Σ_{C} and the total oxygen content Σ_{O} in the powder preferably satisfies the following relationship:

0.4≦Σ_{C}/Σ_{O}≦1.1, particularly preferably 0.6≦Σ_{C}/Σ_{O}≦1.

A very high process reliability, in particular, can be achieved in this way.

The pressing operation is advantageously carried out at pressures of from 100 to 500 MPa. If the pressure is <100 MPa, a sufficient density cannot be achieved during sintering. Pressures of >500 MPa lead to the compounds formed in the reaction of carbon and oxygen not being transported sufficiently quickly out of the sintered body during the sintering process, since the gas permeability is too low. The sintering temperature is preferably in the range from 1800 to 2500° C. Temperatures below 1800° C. lead to very long sintering times or unsatisfactory density and homogeneity. Temperatures above 2500° C. lead to grain growth, which has an unfavourable influence on the advantageous homogeneity of the grain size distribution.

The advantageous particle size of the Mo powder is from 2 to 7 μm and that of the group 5 metal powder is from 4 to 20 μm. The particle size is determined by means of the Fisher method. If the particle size of the group 5 metal is >20 μm, the alloy has an increased tendency to form Kirkendall pores when using a pressure less densification process. If the powder particle size of the group 5 metal is <4 μm, the oxygen content (oxygen adsorbed on the surface of the powder particles) is too high and the advantageous, low oxygen values can be achieved only by means of costly production steps, e.g. particular degassing steps.

If the particle size of the Mo powder exceeds 7 μm, this leads to a reduced sintering activity. If the particle size is below 2 μm, the gas permeability of the green body is significantly poorer. In addition, the green body begins to sinter at relatively low temperatures. Both effects lead to a poorer removal of oxygen during the sintering process.

The powder mixture preferably does not contain any further alloying elements apart from Mo, group 5 metal and carbon source. Impurities are present to an extent typical of these materials.

If further alloying elements are used, their total content must not exceed 15 at %. Alloying elements which do not have an unfavourable effect on the sputtering and etching behaviour have been found to be useful. As suitable alloying metals, mention may be made, for example, of W and Ti.

Sintering is advantageously carried out under vacuum, in an inert atmosphere and/or in a reducing atmosphere. For the present purposes, an inert atmosphere is a gaseous medium which does not react with the alloy components, for example a noble gas. A suitable reducing atmosphere is, in particular, hydrogen. The reaction of C and O to form CO₂ and/or CO is advantageously carried out under vacuum or in an inert atmosphere, for example during the heating operation. The reaction products formed can in this way be removed efficiently. In addition, the formation of hydrides of the group 5 metals is avoided. Final sintering is then preferably carried out in a reducing atmosphere, preferably under hydrogen, for at least part of the time.

Consolidation is preferably followed by a forming process. Forming can, for example, be effected in the case of flat targets by rolling, in the case of tubular targets by extrusion or forging. The preferred degree of deformation is from 45 to 90%. The degree of deformation is defined as follows:

(Aₐ−Aᵤ)/Aₐ×100 (in %)

Aₐ . . . cross-sectional area before forming
Aᵤ . . . cross-sectional area after forming

At degrees of deformation of <45%, the density and uniformity of the sputtering behaviour is adversely affected. Degrees of deformation of >90% have an adverse effect on the manufacturing costs. The forming temperature is preferably from 900° C. to 1500° C. for at least part of the time. For the present purposes, part of the time means that, for example, the first forming steps are carried out at this temperature. The forming temperature can then also be below 900° C. Forming can be carried out either in one step or in a plurality of steps.

If the sputtering target is configured as a flat target, this is preferably soldered to a backplate. Tubular targets can be joined to a support tube, preferably once again by means of a soldering process, or be used as monolithic sputtering targets. As soldering material, preference is given to using indium or an indium-rich alloy.

The invention will be explained by way of example below by means of a production example.

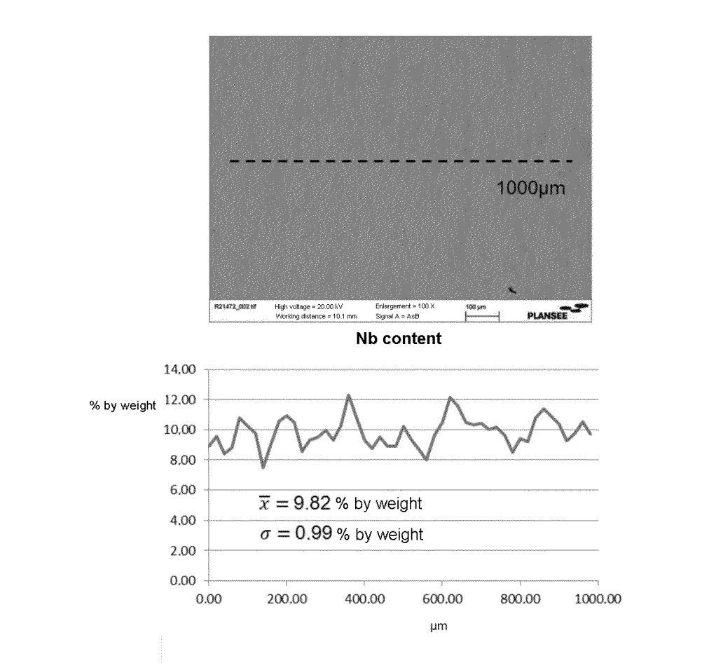

FIG. 1 shows a scanning electron micrograph with WDX scan of rolled Mo-10 at % Nb.

The following powders were used for this purpose:
Mo powder having a Fisher particle size of 4.5 μm, an oxygen content of 0.24 at % and a carbon content of 0.03 at %
Nb powder having a Fisher particle size of 8 μm, an oxygen content of 1.26 at % and a carbon content of 0.46 at %

In order to achieve a Σ_{C}/Σ_{O} value of 0.7 at an amount of Mo of 758 kg and an amount of Nb of 81.6 kg, 0.336 kg of carbon black powder having a Fisher particle size of 0.35 μm was mixed with the Mo and Nb powders in a mechanical mixer. Four plates were produced from this powder mixture by cold isostatic pressing at a pressing pressure of 180 MPa. The plates were sintered at a temperature of 2150° C., with the heating process being carried out over three hours under vacuum up to a temperature of 1200° C. H₂ was then used as process gas. The sintered body had a density of 8.9 g/cm³ (88.6% of the theoretical density), a C content of 0.022 at % and an O content of 0.018 at %. The C/O ratio was 1.22.

The sintered body was subjected to a SEM/EDX examination. Nb and Mo are completely dissolved in one another. No oxides could be detected.

The sintered body was then rolled, with the forming temperature being 1450° C. and the degree of deformation being 78%. A specimen was taken from the rolled plate and ground and polished by means of conventional metallographic methods. The texture of a longitudinal specimen was determined by means of SEM/EBSD.

The following settings were used for this purpose:
acceleration voltage: 20 KV,
working distance: 22 mm,
high-current mode activated,
orifice 120 μm
area scanned 1761×2643 μm²
index step 3 μm.

Evaluation of the inverse pole figure indicated 110 as dominant texture at >2 x random in the longitudinal direction (forming direction). In the direction of the normal (perpendicular to the forming direction), both the 100 and the 111 orientation were measured at >2 x random.

The grain size was measured on a transverse section by means of EBSD. Grain boundaries were defined as all grain orientation differences between two adjacent grains of ≧5°. The grain size distribution was determined by means of quantitative image analysis. The d₅₀ in an evaluation region of 20000 μm² was 15 μm, and the d₉₀ was 35 μm. The d₉₀/d₅₀ ratio was 2.3. This measurement was carried out analogously at ten further places and an average d₉₀/d₅₀ ratio was determined. This was 2.41. The rolled plate was also examined by means of SEM/EDX and SEM/WDX to determine the homogeneity of the Nb distribution. FIG. 1 shows a WDX scan over a distance of 1 mm. The standard deviation of the Nb distribution measured over this distance was 1.02 at %.

The sputtering behaviour of sputtering targets produced in this way was determined by means of sputtering experiments at Ar (argon) pressures in the range from 2.5×10³ to 1×10⁻² mbar and a power of 400 or 800 watts. Soda-lime glass was used as substrate material. The sputtering targets could be sputtered without occurrence of arc processes. The specific electrical resistance of the deposited layers (layer thickness=200 nm) was low and was, depending on the sputtering conditions, from 13.7 to 18.5 μΩcm. The layers had compressive stresses in the range from −1400 to −850 MPa.

1-22. (canceled)

23. A sputtering target, comprising:
an Mo alloy containing at least one metal of group 5 of the Periodic Table;
an average content C_{M} of the group 5 metal of from 5 to 15 at %;
an Mo content of ≧80 at %; and
an average CIO ratio of the sputtering target in (at %/at %) of ≧1.

24. The sputtering target according to claim 23, wherein the group 5 metal is completely dissolved in the Mo.

25. The sputtering target according to claim 23, wherein the sputtering target has a forming texture.

26. The sputtering target according to claim 25, wherein the forming texture has the following dominant orientations:
a. in a forming direction: 110; and
b. perpendicular to the forming direction: at least one orientation selected from the group consisting of 100 and 111.

27. The sputtering target according to claim 25, which further comprises a d₅₀ and a d₉₀ of a grain size distribution, measured perpendicular to a last forming direction, satisfying the following relationship: d₉₀/d₅₀≦5.

28. The sputtering target according to claim 23, which further comprises an O content of ≦0.04 at %.

29. The sputtering target according to claim 23, wherein the sputtering target is free of oxides.

30. The sputtering target according to claim 23, which further comprises a relative density being >99.5% of a theoretical density.

31. The sputtering target according to claim 23, wherein the group 5 metal is uniformly distributed in solution, and a standard deviation a of the group 5 metal distribution satisfies the following relationship: σ≦C_{M}×0.15.

32. The sputtering target according to claim 23, wherein the group 5 metal is Ta or Nb.

33. The sputtering target according to claim 23, which further comprises from 5 to 15 at % of the group 5 metal and a balance of Mo and typical impurities.

34. The sputtering target according to claim 23, wherein the sputtering target is a tubular target.

35. A process for producing a sputtering target, the process comprising the following steps:
a. producing a powder mixture having:
i. ≧80 at % of Mo powder;
ii. a powder of at least one group 5 metal having a content of group 5 metal in the powder mixture of from 5 to 15 at %; and
iii. a C source having an amount of C being selected so that a total content of C Σ_{C} in at % and a total content of O Σ_{O} in at % in the powder mixture satisfies the following relationship:
0.2≦ΣC/ΣO≦1.2; and
b. consolidating the powder mixture.

36. The process according to claim 35, which further comprises producing the sputtering target with:
an Mo alloy containing at least one metal of group 5 of the Periodic Table;
an average content C_{M} of the group 5 metal of from 5 to 15 at %;
an Mo content of ≦80 at %; and
an average CIO ratio of the sputtering target in (at %/at %) of ≦1.

37. The process according to claim 35, which further comprises carrying out a forming process.

38. The process according to claim 35, which further comprises carrying out the consolidating step by:
a. pressing the powder mixture at from 100 to 500 MPa to give a green body; and
b. sintering the green body at a temperature T, where: 1,800° C.<T<2,500° C.

39. The process according to claim 35, wherein the Mo powder has a particle size measured by the Fisher method of from 2 to 7 μm and the group 5 metal has a particle size measured by the Fisher method of from 4 to 20 μm.

40. The process according to claim 35, wherein ΣC and ΣO satisfy the following relationship: 0.4≦ΣC/ΣO≦1.1.

41. The process according to claim 35, wherein the powder mixture contains no further alloying elements apart from typical impurities.

42. The process according to claim 37, which further comprises carrying out the forming process by rolling, extrusion or forging, having a degree of deformation of from 45 to 90%.

43. The process according to claim 38, which further comprises carrying out the sintering step in at least one atmosphere selected from among a vacuum, an inert atmosphere and a reducing atmosphere.

44. The process according to claim 43, which further comprises carrying out the sintering step for a time period being:
at least partly during a heating operation in at least one atmosphere selected from among a vacuum and an inert atmosphere, and
at least partly during a hold time at a sintering temperature in a reducing atmosphere.
